(19) United States
(12) Patent Application Publication
(10) Pub. No.: US 2026/0053032 A1
(43) Pub. Date: Feb. 19, 2026

(54) SENSOR PACKAGE STRUCTURE

(71) Applicant: TONG HSING ELECTRONIC INDUSTRIES, LTD., Taoyuan City (TW)

(72) Inventors: YU-HSIANG LIU, Taoyuan City (TW); LI-CHUN HUNG, Taoyuan City (TW)

(21) Appl. No.: 18/926,647

(22) Filed: Oct. 25, 2024

(30) Foreign Application Priority Data
Aug. 14, 2024 (TW) 113130420

(51) Int. Cl. H01L 23/00; H01L 23/14; H01L 23/31; H01L 27/146

(52) U.S. Cl. CPC H01L 24/49; H01L 23/14; H01L 24/48; H01L 23/3135; H01L 23/315; H01L 2224/48227; H01L 2224/49052; H10F 39/811

(57) ABSTRACT

A sensor package structure includes a substrate, a sensor chip disposed on the substrate, a plurality of first metal wires, a plurality of second metal wires, a ring-shaped supporting layer formed on the sensor chip, and a light-permeable sheet. The first metal wires and the second metal wires are connected to the substrate and the sensor chip. Each edge of a top surface of the sensor chip is provided with at least one of the second metal wires adjacent thereto. Each of the second metal wires has a highest endpoint that is higher than a highest endpoint of any one of the first metal wires with respect to the substrate, and the light-permeable sheet is disposed on the ring-shaped supporting layer and abuts against the highest endpoints of the second metal wires, such that the first metal wires are not in contact with the light-permeable sheet.

### CROSS-REFERENCE TO RELATED PATENT APPLICATION

This application claims the benefit of priority to Taiwan Patent Application No. 113130420, filed on Aug. 14, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a sensor package structure.

### BACKGROUND OF THE DISCLOSURE

A conventional sensor package structure is provided with a supporting layer for carrying a light-permeable sheet thereof, but the light-permeable sheet often ends up pressing against at least one metal wire that is provided for signal transmission between a substrate and a sensor chip due to an excessive weight or tilting of the light-permeable sheet, such that the at least one metal wire pressed by the light-permeable sheet may have a deformation that affects the signal transmission.

### SUMMARY OF THE DISCLOSURE

In response to the above-referenced technical inadequacies, the present disclosure provides a sensor package structure for effectively improving on the issues associated with conventional sensor package structures.

In order to solve the above-mentioned problems, one of the technical aspects adopted by the present disclosure is to provide a sensor package structure, which includes a substrate, a sensor chip, a plurality of first metal wires, a plurality of second metal wires, a ring-shaped supporting layer, and a light-permeable sheet. The substrate has an upper surface and a lower surface that is opposite to the upper surface. The upper surface has a chip-bonding region, and the substrate includes a plurality of first bonding pads and a plurality of second bonding pads. The first bonding pads and the second bonding pads are arranged outside of the chip-bonding region. The sensor chip is disposed on the chip-bonding region of the substrate. A top surface of the sensor chip includes a sensing region and a carrying region that surrounds the sensing region, and the sensor chip includes a plurality of first connection pads and a plurality of second connection pads. The first connection pads are arranged on the carrying region. The first connection pads are arranged along edges of the top surface. The second connection pads are arranged on the carrying region. Each of the edges of the top surface is provided with at least one of the second connection pads arranged adjacent thereto, and the second connection pads do not have any signal transmission function. One end of the first metal wires is connected to the first bonding pads, and another end of the first metal wires is connected to the first connection pads, such that the substrate and the sensor chip are electrically coupled to each other through the first metal wires. One end of the second metal wires is connected to the second bonding pads, and another end of the second metal wires is connected to the second connection pads. Each of the second metal wires has a highest endpoint that is higher than a highest endpoint of any one of the first metal wires with respect to the substrate. The ring-shaped supporting layer is formed on the carrying region of the sensor chip. The light-permeable sheet is disposed on the ring-shaped supporting layer and abuts against the highest endpoints of the second metal wires, and the first metal wires are not in contact with the light-permeable sheet. The light-permeable sheet, the ring-shaped supporting layer, and the top surface of the sensor chip jointly define an enclosed space, and the sensing region is located in the enclosed space.

In order to solve the above-mentioned problems, another one of the technical aspects adopted by the present disclosure is to provide a sensor package structure, which includes a substrate, a sensor chip, a plurality of first metal wires, a plurality of second metal wires, a ring-shaped supporting layer, and a light-permeable sheet. The substrate has an upper surface and a lower surface that is opposite to the upper surface. The upper surface has a chip-bonding region, and the substrate includes a plurality of first bonding pads and a plurality of second bonding pads. The first bonding pads and the second bonding pads are arranged outside of the chip-bonding region. The sensor chip is disposed on the chip-bonding region of the substrate. A top surface of the sensor chip includes a sensing region and a carrying region that surrounds the sensing region, and the sensor chip includes a plurality of first connection pads and a plurality of second connection pads. The first connection pads are arranged on the carrying region. The first connection pads are arranged along edges of the top surface. The second connection pads are arranged on the carrying region. Each of corners of the top surface is provided with one of the second connection pads arranged adjacent thereto, and the second connection pads do not have any signal transmission function. One end of the first metal wires is connected to the first bonding pads, and another end of the first metal wires is connected to the first connection pads, such that the substrate and the sensor chip are electrically coupled to each other through the first metal wires. One end of the second metal wires is connected to the second bonding pads, and another end of the second metal wires is connected to the second connection pads. Each of the second metal wires has a highest endpoint that is higher than a highest endpoint of any one of the first metal wires with respect to the substrate. The ring-shaped supporting layer is formed on the carrying region of the sensor chip. The light-permeable sheet is disposed on the ring-shaped supporting layer and abuts against the highest endpoints of the second metal wires, and the first metal wires are not in contact with the light-permeable sheet. The light-permeable sheet, the ring-shaped supporting layer, and the top surface of the sensor chip jointly define an enclosed space, and the sensing region is located in the enclosed space.

Therefore, the second metal wires of the sensor package structure in the present disclosure are provided without any signal transmission function and can be cooperated with the ring-shaped supporting layer to jointly carry the light-permeable sheet through the structural arrangement of the second metal wires, thereby effectively preventing any one of the first metal wires from being compressed by the light-permeable sheet so as to maintain the signal transmission performance between the substrate and the sensor chip.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a sensor package structure according to a first embodiment of the present disclosure;

FIG. 2 is a schematic perspective view showing the sensor package structure of FIG. 1 when a ring-shaped supporting layer, a light-permeable sheet, and an encapsulant are omitted;

FIG. 3 is a schematic top view of FIG. 2;

FIG. 4 is a schematic cross-sectional view taken along line IV-IV of FIG. 1;

FIG. 5 is a schematic enlarged view of part V of FIG. 4;

FIG. 6 is a schematic top view showing a portion of the sensor package structure in another configuration corresponding to that of FIG. 2;

FIG. 7 is a schematic cross-sectional view showing the sensor package structure of FIG. 4 in another configuration;

FIG. 8 is a schematic cross-sectional view showing an assembling process of the light-permeable sheet according to the first embodiment of the present disclosure;

FIG. 9 is a schematic enlarged view showing a portion of the sensor package structure in another configuration corresponding to that of FIG. 5;

FIG. 10 is a schematic perspective view of the sensor package structure according to a second embodiment of the present disclosure;

FIG. 11 is a schematic cross-sectional view taken along line XI-XI of FIG. 10;

FIG. 12 is a schematic top view showing the sensor package structure when the ring-shaped supporting layer, the light-permeable sheet, and the encapsulant are omitted according to the second embodiment of the present disclosure; and

FIG. 13 is a schematic top view showing a portion of the sensor package structure in another configuration corresponding to that of FIG. 12.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on. ” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

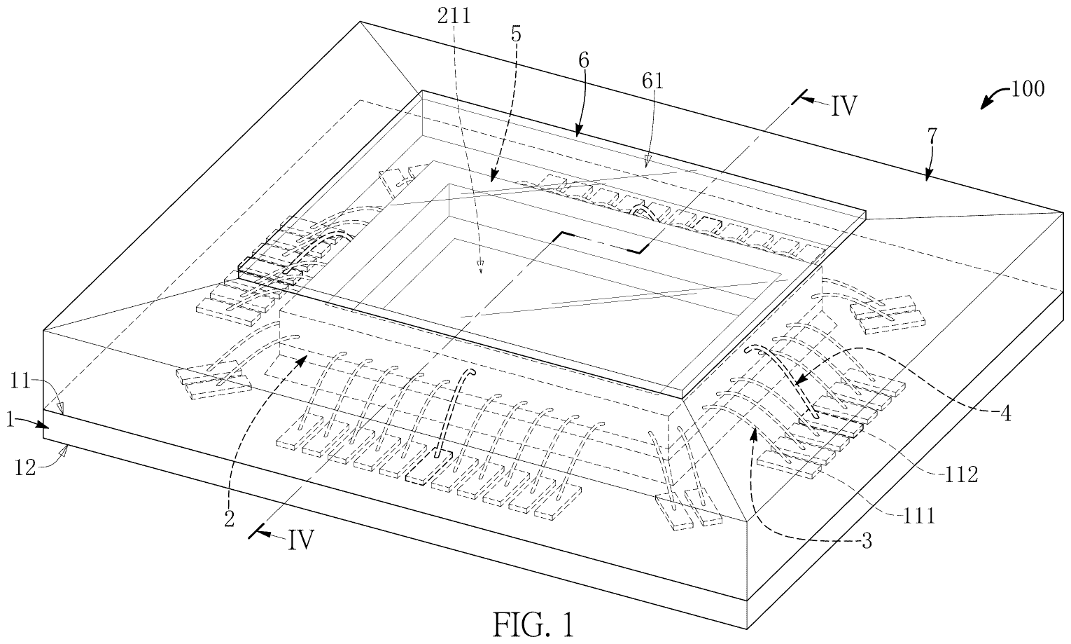

Referring to FIG. 1 to FIG. 9, a first embodiment of the present disclosure is provided. As shown in FIG. 1, the present embodiment provides a sensor package structure 100, which includes a substrate 1, a sensor chip 2 disposed on the substrate 1, a plurality of first metal wires 3 connected to the sensor chip 2 and the substrate 1, a plurality of second metal wires 4 connected to the sensor chip 2 and the substrate 1, a ring-shaped supporting layer 5 disposed on the sensor chip 2, a light-permeable sheet 6 disposed on the ring-shaped supporting layer 5 and the second metal wires 4, and an encapsulant 7 that is formed on the substrate 1.

It should be noted that the sensor package structure 100 in the present embodiment includes the above components, but can be adjusted or changed according to design requirements. For example, in other embodiments of the present disclosure not shown in the drawings, the encapsulant 7 of the sensor package structure 100 can be omitted or can be replaced by other components according to practical requirements. The structure and connection relationship of each component of the sensor package structure 100 are recited in the following description.

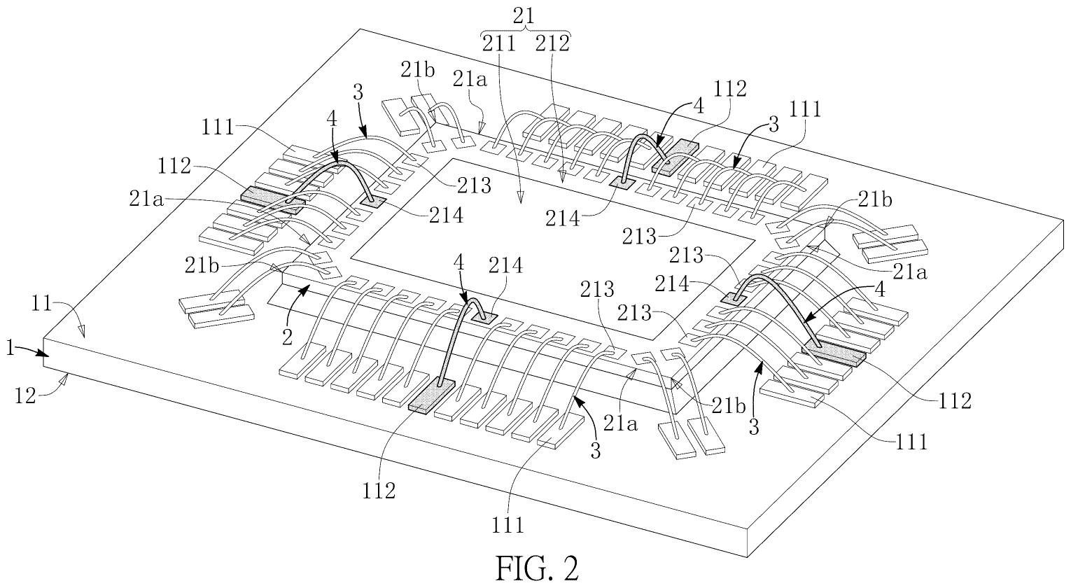

As shown in FIG. 2 to FIG. 5, the substrate 1 of the present embodiment has a square shape or a rectangular shape, but the present disclosure is not limited thereto. The substrate 1 has an upper surface 11 and a lower surface 12 that is opposite to the upper surface 11. The upper surface 11 of the substrate 1 includes a chip-bonding region 113 arranged approximately on a center portion thereof, and the substrate 1 includes a plurality of first bonding pads 111 and a plurality of second bonding pads 112. The first bonding pads 111 and the second bonding pads 112 are disposed on the upper surface 11 and are arranged outside of the chip-bonding region 113. The first bonding pads 111 and the second bonding pads 112 in the present embodiment are jointly in an annular arrangement, but the present disclosure is not limited thereto.

Moreover, the substrate 1 can be further provided with a plurality of solder balls 8 disposed on the lower surface 12 thereof. The substrate 1 can be soldered onto an electronic component (not shown in the drawings) through the solder balls 8, thereby electrically connecting the sensor package structure 100 to the electronic component.

The sensor chip 2 in the present embodiment can have a square shape or a rectangular shape and is an image sensing chip, but the present disclosure is not limited thereto. The sensor chip 2 is fixed onto the chip-bonding region 113 of the substrate 1 through a bottom surface 22 thereof. In other words, the sensor chip 2 is arranged to be surrounded on the inside of the first bonding pads 111 and the second bonding pads 112. Moreover, a top surface 21 of the sensor chip 2 has a sensing region 211 and a carrying region 212 that has an annular shape surrounding the sensing region 211.

Specifically, the sensor chip 2 in the present embodiment includes a plurality of first connection pads 213 and a plurality of second connection pads 214. The first connection pads 213 and the second connection pads 214 are arranged on the carrying region 212 (i.e., the first connection pads 213 and the second connection pads 214 are arranged outside of the sensing region 211). Moreover, a quantity of the second connection pads 214 is preferably less than a quantity of the first connection pads 213. The number and positions of the first connection pads 213 of the sensor chip 2 in the present embodiment correspond to those of the first bonding pads 111 of the substrate 1, and the number and positions of the second connection pads 214 of the sensor chip 2 in the present embodiment correspond to those of the second bonding pads 112 of the substrate 1.

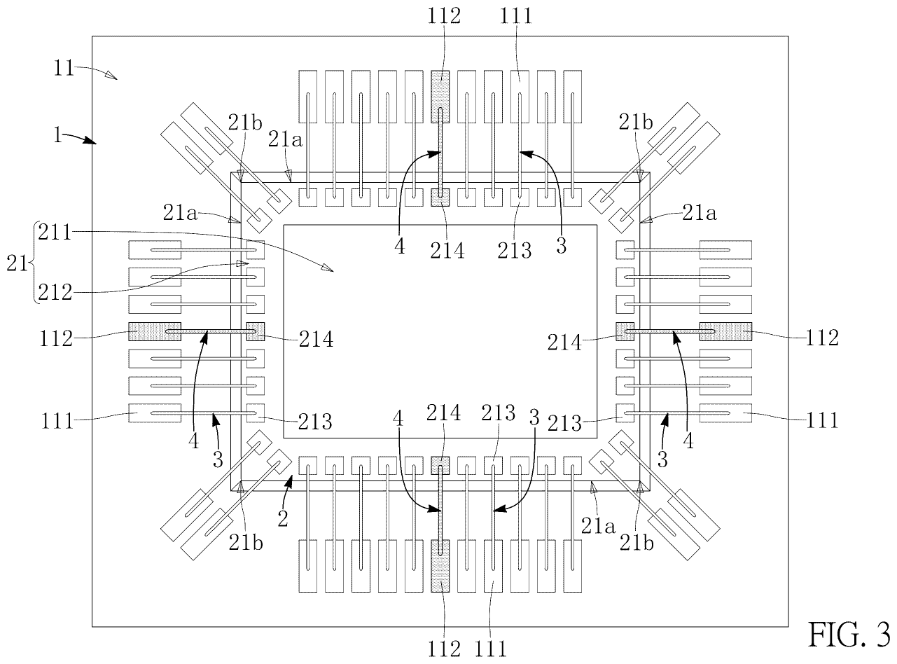

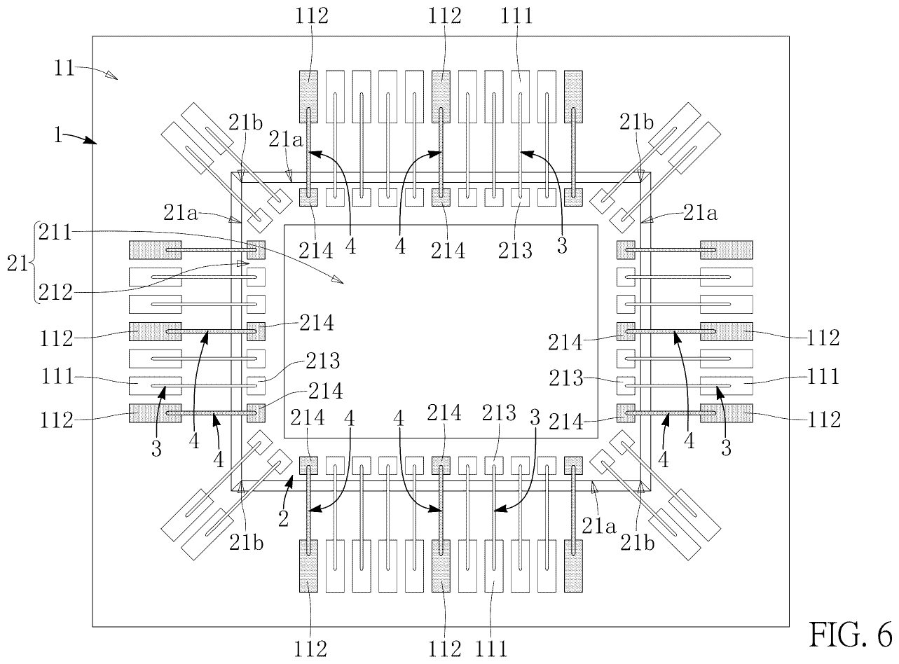

Furthermore, the first connection pads 213 are arranged along edges 21a of the top surface 21, and each of the edges 21a of the top surface 21 is provided with at least one of the second connection pads 214 arranged adjacent thereto. In the present embodiment, for each of the edges 21a of the top surface 21 of the sensor chip 2, the corresponding first connection pads 213 and the at least one of the second connection pads 214 are arranged in one row. In other words, the first connection pads 213 and the second connection pads 214 are jointly in a rectangular ring-shaped arrangement. For each of the edges 21a of the top surface 21 of the sensor chip 2, a quantity of the at least one of the second connection pads 214 can be adjusted or changed according to practical requirements (e.g., the quantity of the at least one of the second connection pads 214 can be one as shown in FIG. 2 and FIG. 3; or, the quantity of the at least one of the second connection pads 214 can be more than one as shown in FIG. 6), but the present disclosure is not limited thereto.

As shown in FIG. 2 to FIG. 5, one end of the first metal wires 3 is connected to the first bonding pads 111, and another end of the first metal wires 3 is connected to the first connection pads 213, such that the substrate 1 and the sensor chip 2 are electrically coupled to each other through the first metal wires 3. Specifically, a sensing function or a signal transmission function of the sensor chip 2 in the present embodiment is implemented by using the first metal wires 3 to be cooperated with the first bonding pads 111 and the first connection pads 213. In other words, any one of the first metal wires 3 is not suitable to be compressed or to be deformed.

One end of the second metal wires 4 is connected to the second bonding pads 112, and another end of the second metal wires 4 is connected to the second connection pads 214, but the second connection pads 214 do not have any signal transmission function. In other words, the second metal wires 4 can be compressed or deformed.

Specifically, the second bonding pads 112 and the second connection pads 214 are grounding pads, the substrate 1 and the sensor chip 2 are commonly grounded through the second metal wires 4, and the second metal wires 4 are configured to support the light-permeable sheet 6. In other words, the second bonding pads 112 and the second connection pads 214 do not have any electrical function, and the second metal wires 4 are configured to only support the light-permeable sheet 6.

Moreover, each of the second metal wires 4 has a highest endpoint 41 that is higher than a highest endpoint 31 of any one of the first metal wires 3 with respect to the substrate 1, and the highest endpoints 41 of the second metal wires 4 are substantially located at a same plane (e.g., the highest endpoints 41 of any two of the second metal wires 4 can have a height difference therebetween that is less than or equal to 5 μm).

It should be noted that in order to implement the above configuration of the first metal wires 3 and the second metal wires 4, each of the second metal wires 4 has a normal bond structure being different from a wiring structure of any one of the first metal wires 3 that can be a reserve bond structure or an ultra-low wiring structure, but the present disclosure is not limited thereto. In addition, a material of each of the second metal wires 4 is different from that of any one of the first metal wires 3, and a structural strength of each of the second metal wires 4 is greater than that of any one of the first metal wires 3.

Specifically, the highest endpoint 31 of each of the first metal wires 3 is spaced apart from the top surface 21 of the sensor chip 2 by a first distance D1, and the highest endpoint 41 of each of the second metal wires 4 is spaced apart from the top surface 21 of the sensor chip 2 by a second distance D2 that is preferably greater than the first distance D1 by at least 10 μm or that can be within a range from 120% to 250% of the first distance D1. In the present embodiment, the first distance D1 is within a range from 65 μm to 85 μm, and the second distance D2 is within a range from 140 μm to 160 μm, but the present disclosure is not limited thereto.

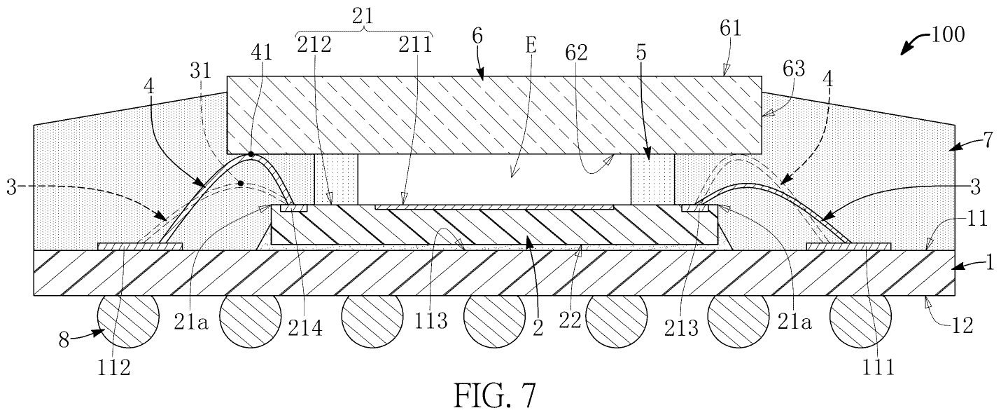

The ring-shaped supporting layer 5 is disposed on the carrying region 212 of the sensor chip 2 and surrounds the sensing region 211 of the sensor chip 2. In the present embodiment, each of the first connection pads 213 and a part of the corresponding first metal wire 3 connected thereto are embedded in the ring-shaped supporting layer 5, each of the second connection pads 214 and a part of the corresponding second metal wire 4 connected thereto are embedded in the ring-shaped supporting layer 5, and other parts of each of the first metal wires 3 and other parts of each of the second metal wires 4 are embedded in the encapsulant 7, but the present disclosure is not limited thereto. For example, as shown in FIG. 7, the first connection pads 213 and the second connection pads 214 are arranged outside of the ring-shaped supporting layer 5 and are embedded in the encapsulant 7, and the first metal wires 3 and the second metal wires 4 are entirely embedded in the encapsulant 7.

As shown in FIG. 2 to FIG. 4, the light-permeable sheet 6 in the present embodiment is a transparent and flat glass board, but the present disclosure is not limited thereto. The light-permeable sheet 6 in the present embodiment has an outer surface 61, an inner surface 62 opposite to the outer surface 61, and a surrounding lateral surface 63 that is arranged between the outer surface 61 and the inner surface 62. The light-permeable sheet 6 (e.g., the inner surface 62) is disposed on the ring-shaped supporting layer 5 and abuts against the highest endpoints 41 of the second metal wires 4, and the first metal wires 3 are not in contact with the light-permeable sheet 6.

Accordingly, the second metal wires 4 of the sensor package structure 100 in the present embodiment are provided without any signal transmission function and can be cooperated with the ring-shaped supporting layer 5 to jointly carry the light-permeable sheet 6 through the structural arrangement of the second metal wires 4, thereby effectively preventing any one of the first metal wires 3 from being compressed by the light-permeable sheet 6 so as to maintain the signal transmission performance between the substrate 1 and the sensor chip 2.

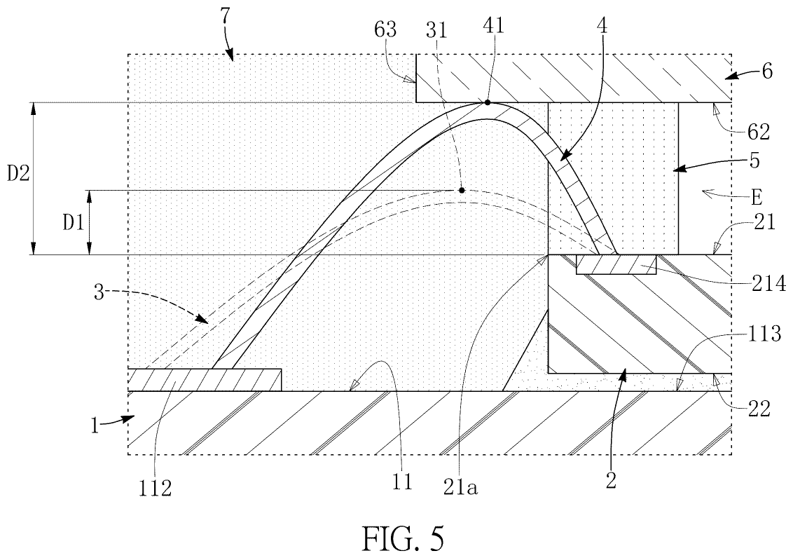

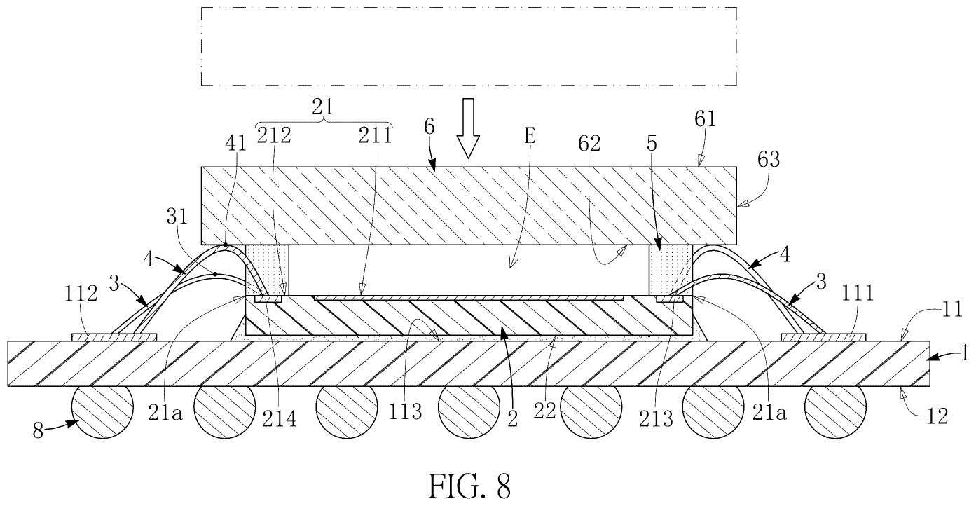

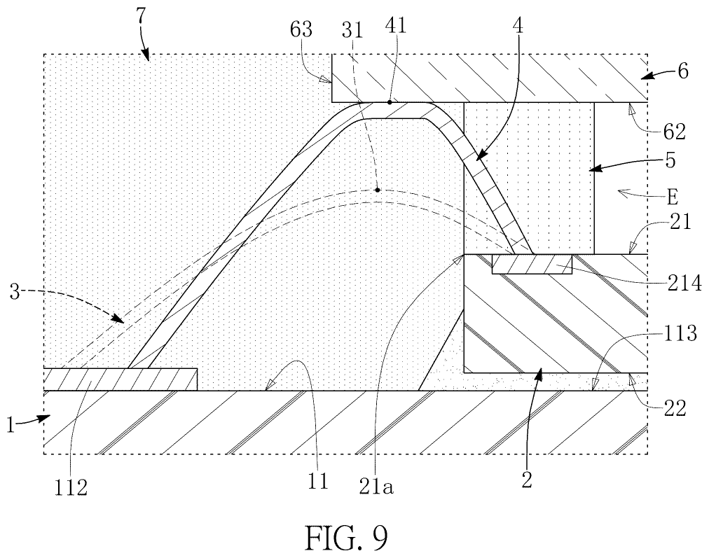

It should be noted that as shown in FIG. 8, the light-permeable sheet 6 in the present embodiment can be placed onto the ring-shaped supporting layer 5 and the highest endpoints 41 of the second metal wires 4 in a free fall manner. For example, a catching device is used to hold the light-permeable sheet 6 and is configured to release the light-permeable sheet 6 when being located above the ring-shaped supporting layer 5 by a predetermined distance. Accordingly, each of the second metal wires 4 may have a deformation being less than 8μm at the highest endpoint 41 thereof. For example, the metal wire 4 can almost have no deformation as shown in FIG. 5; or, the metal wire 4 can have a slight deformation as shown in FIG. 9.

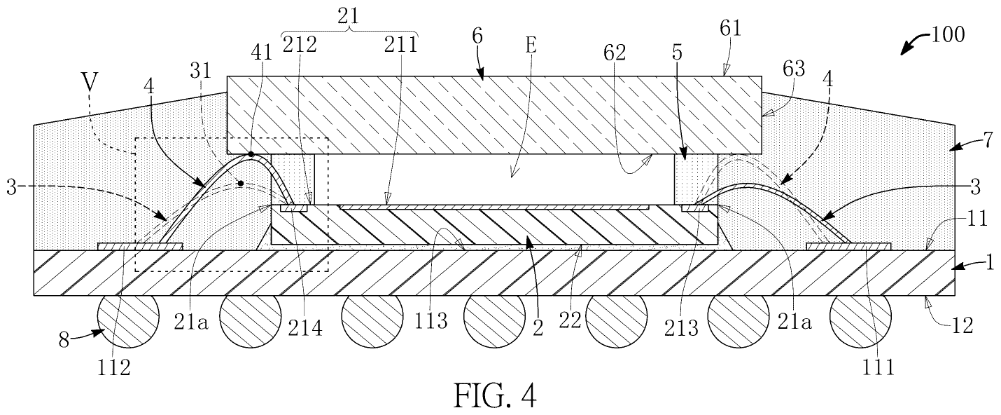

In other words, as shown in FIG. 4, the light-permeable sheet 6, the ring-shaped supporting layer 5, and the top surface 21 of the sensor chip 2 jointly define an enclosed space E, and the sensing region 211 is located in the enclosed space E. Moreover, the encapsulant 7 is formed on the upper surface 11 of the substrate 1, and at least part of each of the first metal wires 3, at least part of each of the second metal wires 4, the sensor chip 2, the ring-shaped supporting layer 5, and the light-permeable sheet 6 are embedded in the encapsulant 7. Furthermore, the outer surface 61 of the light-permeable sheet 6 is at least partially exposed from the encapsulant 7.

### Second Embodiment

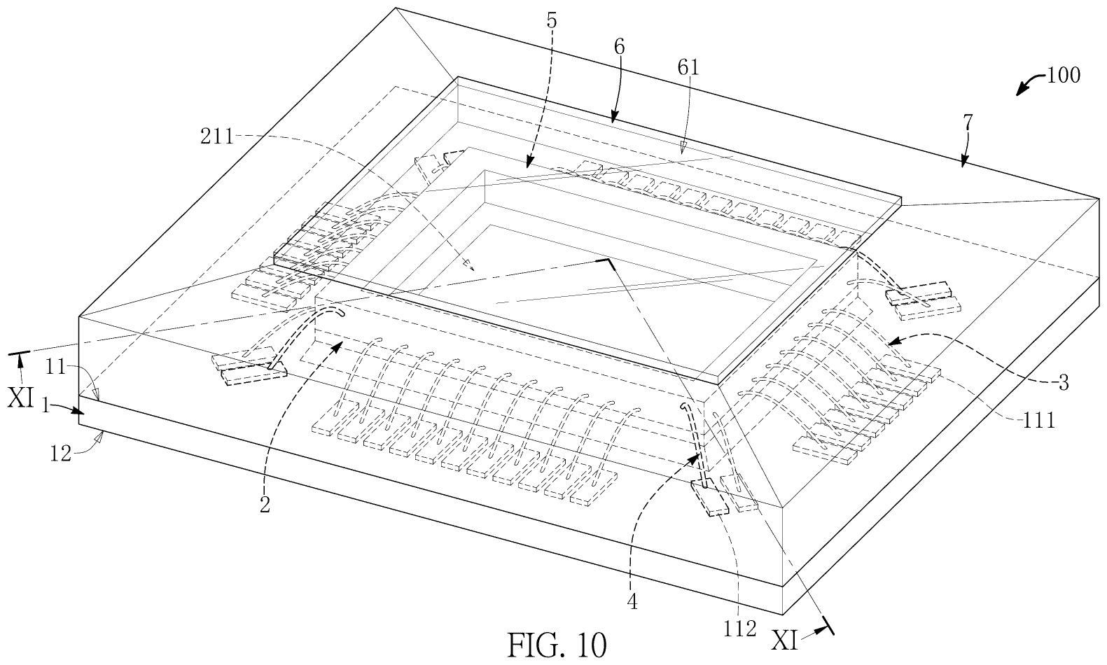

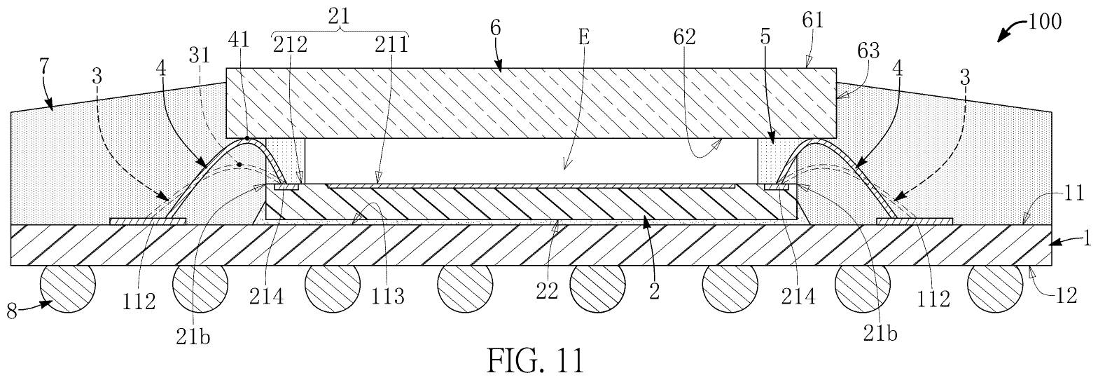

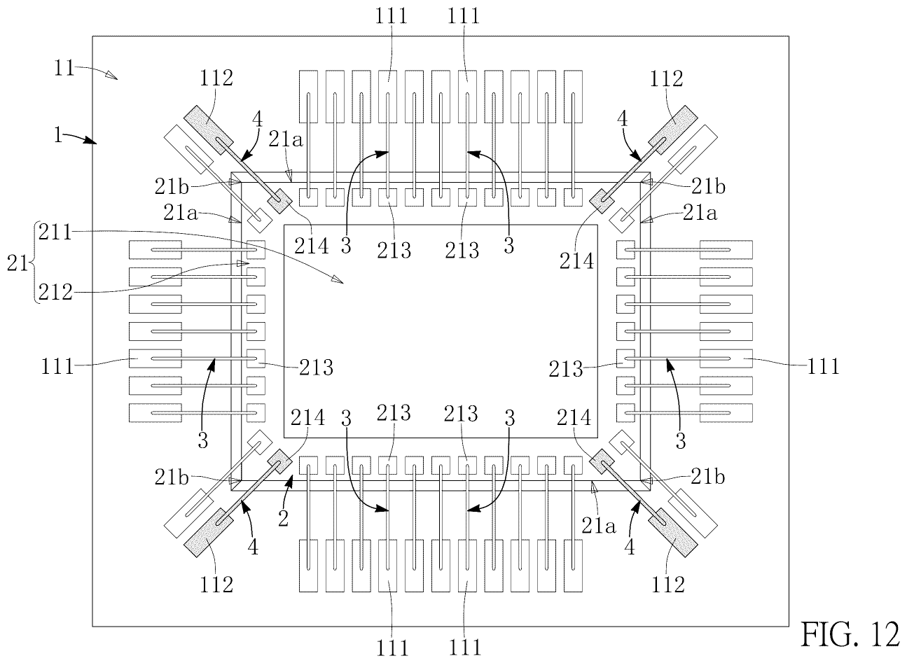

Referring to FIG. 10 to FIG. 13, a second embodiment of the present disclosure, which is similar to the first embodiment of the present disclosure, is provided. For the sake of brevity, descriptions of the same components in the first and second embodiments of the present disclosure (e.g., the arrangement of the second bonding pads 112, the second connection pads 214, and the second metal wires 4) will be omitted herein, and the following description only discloses different features between the first and second embodiments.

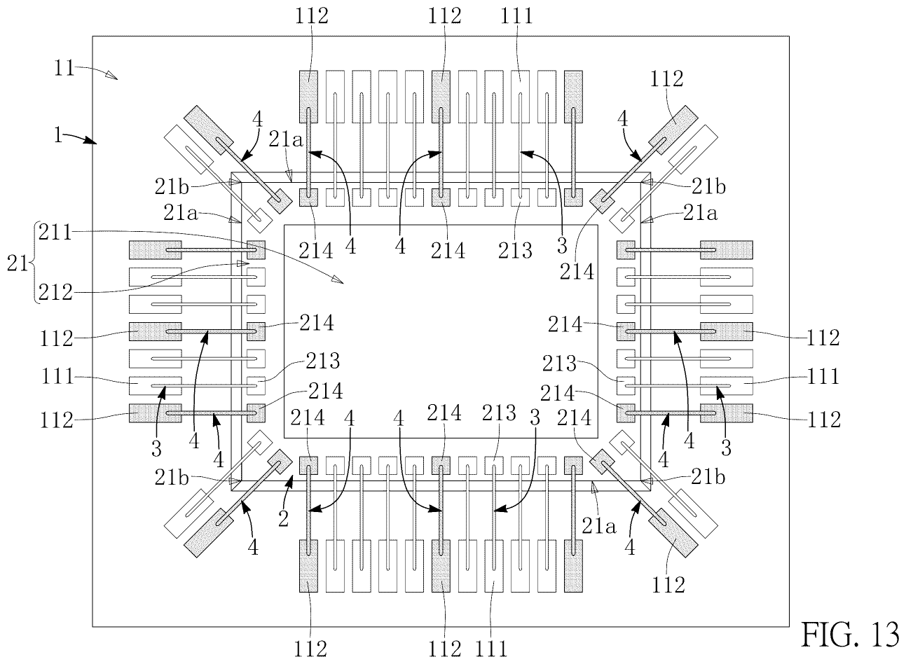

As shown in FIG. 10 to FIG. 12 of the present embodiment, each of corners 21b of the top surface 21 of the sensor chip 2 is provided with one of the second connection pads 214 arranged adjacent thereto, so that the (four) corners of the light-permeable sheet 6 can be supported by the second metal wires 4, thereby effectively preventing the light-permeable sheet 6 from being tilted. Or, as shown in FIG. 13, each of the corners 21b of the top surface 21 of the sensor chip 2 is provided with one of the second connection pads 214 arranged adjacent thereto, and each of the edges 21a of the top surface 21 can be provided with at least one of the second connection pads 214 arranged adjacent thereto, thereby effectively increasing the supporting strength of the second metal wires 4 provided for the light-permeable sheet 6.

### Beneficial Effects of the Embodiments

In conclusion, the second metal wires of the sensor package structure in the present disclosure are provided without any signal transmission function and can be cooperated with the ring-shaped supporting layer to jointly carry the light-permeable sheet through the structural arrangement of the second metal wires, thereby effectively preventing any one of the first metal wires from being compressed by the light-permeable sheet so as to maintain the signal transmission performance between the substrate and the sensor chip.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A sensor package structure, comprising:
a substrate having an upper surface and a lower surface that is opposite to the upper surface, wherein the upper surface has a chip-bonding region, and the substrate includes a plurality of first bonding pads and a plurality of second bonding pads, and wherein the first bonding pads and the second bonding pads are arranged outside of the chip-bonding region;
a sensor chip disposed on the chip-bonding region of the substrate, wherein a top surface of the sensor chip includes a sensing region and a carrying region that surrounds the sensing region, and the sensor chip includes:
a plurality of first connection pads arranged on the carrying region, wherein the first connection pads are arranged along edges of the top surface; and
a plurality of second connection pads arranged on the carrying region, wherein each of the edges of the top surface is provided with at least one of the second connection pads arranged adjacent thereto, and the second connection pads do not have any signal transmission function;
a plurality of first metal wires, wherein one end of the first metal wires is connected to the first bonding pads, and another end of the first metal wires is connected to the first connection pads, such that the substrate and the sensor chip are electrically coupled to each other through the first metal wires;
a plurality of second metal wires, wherein one end of the second metal wires is connected to the second bonding pads, and another end of the second metal wires is connected to the second connection pads, and wherein each of the second metal wires has a highest endpoint that is higher than a highest endpoint of any one of the first metal wires with respect to the substrate;
a ring-shaped supporting layer formed on the carrying region of the sensor chip; and
a light-permeable sheet disposed on the ring-shaped supporting layer and abutting against the highest endpoints of the second metal wires, and the first metal wires being not in contact with the light-permeable sheet, wherein the light-permeable sheet, the ring-shaped supporting layer, and the top surface of the sensor chip jointly define an enclosed space, and wherein the sensing region is located in the enclosed space.

2. The sensor package structure according to claim 1, wherein each of the second metal wires has a deformation being less than 8 μm at the highest endpoint thereof.

3. The sensor package structure according to claim 1, wherein the second bonding pads and the second connection pads are grounding pads, and the substrate and the sensor chip are commonly grounded through the second metal wires.

4. The sensor package structure according to claim 1, wherein the second bonding pads and the second connection pads do not have any electrical function, and the second metal wires are configured to only support the light-permeable sheet.

5. The sensor package structure according to claim 1, wherein, for each of the edges of the top surface of the sensor chip, the corresponding first connection pads and the at least one of the second connection pads are arranged in one row.

6. The sensor package structure according to claim 1, wherein the highest endpoint of each of the first metal wires is spaced apart from the top surface of the sensor chip by a first distance, and the highest endpoint of each of the second metal wires is spaced apart from the top surface of the sensor chip by a second distance that is greater than the first distance by at least 10 μm.

7. The sensor package structure according to claim 1, wherein the highest endpoint of each of the first metal wires is spaced apart from the top surface of the sensor chip by a first distance, and the highest endpoint of each of the second metal wires is spaced apart from the top surface of the sensor chip by a second distance that is within a range from 120% to 250% of the first distance.

8. The sensor package structure according to claim 1, wherein a material of each of the second metal wires is different from that of any one of the first metal wires, and a structural strength of each of the second metal wires is greater than a structural strength of any one of the first metal wires.

9. The sensor package structure according to claim 1, wherein each of the second metal wires has a normal bond structure that is different from a wiring structure of any one of the first metal wires.

10. The sensor package structure according to claim 1, further comprising an encapsulant formed on the upper surface of the substrate, wherein at least part of each of the first metal wires, at least part of each of the second metal wires, the sensor chip, the ring-shaped supporting layer, and the light-permeable sheet are embedded in the encapsulant, and an outer surface of the light-permeable sheet is at least partially exposed from the encapsulant.

11. The sensor package structure according to claim 10, wherein each of the first connection pads and a part of the corresponding first metal wire connected thereto are embedded in the ring-shaped supporting layer, and other parts of the first metal wires are embedded in the encapsulant, and wherein each of the second connection pads and a part of the corresponding second metal wire connected thereto are embedded in the ring-shaped supporting layer, and other parts of the second metal wires are embedded in the encapsulant.

12. The sensor package structure according to claim 10, wherein the first connection pads and the second connection pads are arranged outside of the ring-shaped supporting layer and are embedded in the encapsulant, and the first metal wires and the second metal wires are entirely embedded in the encapsulant.

13. A sensor package structure, comprising:
a substrate having an upper surface and a lower surface that is opposite to the upper surface, wherein the upper surface has a chip-bonding region, and the substrate includes a plurality of first bonding pads and a plurality of second bonding pads, and wherein the first bonding pads and the second bonding pads are arranged outside of the chip-bonding region;
a sensor chip disposed on the chip-bonding region of the substrate, wherein a top surface of the sensor chip includes a sensing region and a carrying region that surrounds the sensing region, and the sensor chip includes:
a plurality of first connection pads arranged on the carrying region, wherein the first connection pads are arranged along edges of the top surface; and
a plurality of second connection pads arranged on the carrying region, wherein each of corners of the top surface is provided with one of the second connection pads arranged adjacent thereto, and the second connection pads do not have any signal transmission function;
a plurality of first metal wires, wherein one end of the first metal wires is connected to the first bonding pads, and another end of the first metal wires is connected to the first connection pads, such that the substrate and the sensor chip are electrically coupled to each other through the first metal wires;
a plurality of second metal wires, wherein one end of the second metal wires is connected to the second bonding pads, and another end of the second metal wires is connected to the second connection pads, and wherein each of the second metal wires has a highest endpoint that is higher than a highest endpoint of any one of the first metal wires with respect to the substrate;
a ring-shaped supporting layer formed on the carrying region of the sensor chip; and
a light-permeable sheet disposed on the ring-shaped supporting layer and abutting against the highest endpoints of the second metal wires, and the first metal wires being not in contact with the light-permeable sheet, wherein the light-permeable sheet, the ring-shaped supporting layer, and the top surface of the sensor chip jointly define an enclosed space, and wherein the sensing region is located in the enclosed space.

14. The sensor package structure according to claim 13, wherein each of the edges of the top surface of the sensor chip is provided with at least one of the second connection pads arranged adjacent thereto.

15. The sensor package structure according to claim 13, wherein the first connection pads and the second connection pads are jointly in a rectangular ring-shaped arrangement.
